(19) United States
(12) Patent Application Publication
(10) Pub. No.: US 2011/0199269 A1
(43) Pub. Date: Aug. 18, 2011

(54) ANTENNA PATTERN FRAME, ELECTRONIC DEVICE PROVIDED WITH ANTENNA PATTERN FRAME AND METHOD FOR MANUFACTURING ELECTRONIC DEVICE

(75) Inventors: Jae Suk SUNG, Yongin (KR); Ha Ryong HONG, Hwaseong (KR); Sung Eun CHO, Suwon (KR); Tae Sung KIM, Seoul (KR); Byung Hwa LEE, Suwon (KR); Hyun Sam MUN, Suwon (KR); Dae Seong JEON, Suwon (KR); Duk Woo LEE, Suwon (KR); Dae Kyu LEE, Suwon (KR); Chan Gwang AN, Suwon (KR)

(73) Assignee: SAMSUNG ELECTRO-MECHANICS CO., LTD., Gyunggi-do (KR)

(21) Appl. No.: 13/023,125

(22) Filed: Feb. 8, 2011

(30) Foreign Application Priority Data
Feb. 17, 2010 (KR) 10-2010-0014298

(51) Int. Cl. H01Q 1/24; H01Q 1/40; H05K 13/00

(52) U.S. Cl. 343/702; 343/873; 29/601

(57) ABSTRACT

There is provided an antenna pattern frame according to one embodiment of the present invention, including: a radiator frame that has an insertion groove formed on one surface of the radiator frame and is provided with a through part connected from one point of the insertion groove to an opposite surface to the one surface of the radiator frame; and a wire antenna that includes an antenna pattern part formed to be inserted into the insertion groove and an interconnection part formed to be exposed to the opposite surface by extending from the antenna pattern part and penetrating through the through part.

### CROSS-REFERENCE TO RELATED APPLICATIONS

This application claims the priority of Korean Patent Application No. 10-2010-0014298 filed on Feb. 17, 2010, in the Korean Intellectual Property Office, the disclosure of which is incorporated herein by reference.

### BACKGROUND OF THE INVENTION

1. Field of the Invention

The present invention relates to an antenna pattern part formed of a conductive wire, an electronic device provided with the antenna pattern frame, and a method for manufacturing the electronic device.

2. Description of the Related Art

Electronic devices such as mobile communication terminals, for example, cellular phones, PDAs, navigation devices, notebook computers, or the like, are necessities in modern society. The mobile communication terminals are being developed to have functions, such as CDMA, wireless LAN, GSM, DMB, or the like. One of the most important parts that enable the above functions is an antenna.

The antenna currently used in a mobile communication terminal has evolved from an exterior type antenna such as a rod antenna or a helical antenna to an interior type antenna wherein an antenna is mounted in the terminal.

There have been problems in that the exterior type is vulnerable to external impact and the interior type increases the volume of the terminal.

In order to solve the problems, research to integrate the electronic device, i.e., the mobile communication terminal and the antenna has been actively conducted.

Recently, the applicant has proposed a method that forms an antenna pattern frame by performing injection molding on a radiator in order to embed an antenna in a case of an electronic device and embeds the radiator formed on the surface of the antenna pattern frame into the case of the electronic device by performing injection molding, i.e., double injection molding on the antenna pattern frame.

In the above-mentioned antenna, since the antenna pattern is formed by pressing a metal plate, a radiator, there have been problems in that the length of the antenna pattern is long and the wasted amount of the antenna pattern is increased with the increase in the area of the antenna pattern to increase the material cost.

Further, when the injection molding is performed in order to form the antenna pattern frame having an antenna pattern part formed on the surface thereof, it is very important to dispose the antenna pattern part in a manufacturing mold of the antenna pattern frame at the time of determining how accurately the antenna pattern part is disposed the case of the electronic device.

In the case of an antenna for a low frequency band, a wavelength is long and thus, the length of the antenna becomes long. There has been a problem in that as the length of the antenna pattern becomes long, the structure of the manufacturing mold to fix the antenna pattern is complicated.

### SUMMARY OF THE INVENTION

An aspect of the present invention provides an antenna pattern frame capable of fixing a wire antenna to an injection molded part without using an injection molding method to fix a radiator to a manufacturing mold.

Another aspect of the present invention provides an electronic device having a wire antenna embedded therein by using an antenna pattern frame to which the wire antenna is fixed.

Still another aspect of the present invention provides a method for manufacturing an electronic device having a wire antenna embedded therein by using an antenna pattern frame to which the wire antenna is fixed.

According to an aspect of the present invention, there is provided an antenna pattern frame, including: a radiator frame that has an insertion groove formed on one surface of the radiator frame and is provided with a through part connected from one point of the insertion groove to an opposite surface to the one surface of the radiator frame; and a wire antenna that includes an antenna pattern part formed to be inserted into the insertion groove and an interconnection part formed to be exposed to the opposite surface by extending from the antenna pattern part and penetrating through the through part.

The insertion groove may be formed at the same depth as the diameter or thickness of the wire antenna.

The insertion groove may be formed to have a depth larger than the diameter or thickness of the wire antenna.

The antenna pattern frame may further include a coating part formed on the one surface of the radiator frame in order to increase the adhesion between the wire antenna and the radiator frame.

The insertion groove may be surface-treated by thermal bonding.

The insertion groove may be formed on the side surface, the upper surface, or the side surface and the upper surface of the radiator frame.

The insertion groove may be formed on the radiator frame so that the wire antenna is a roof antenna.

The wire antenna may be separated in plural.

The interconnection part may include an end of an interconnection pin formed to be bent at the opposite surface and the opposite surface of the radiator frame may be provided with an end connection groove to which the end of the interconnection part is fixed.

The interconnection part may be exposed at the opposite surface in a spiral shape.

According to another aspect of the present invention, there is provided an electronic device, including: an antenna pattern frame that has an insertion groove formed on one surface of the antenna pattern frame and is provided with an interconnection part formed on an opposite surface to the one surface, a wire antenna being inserted into the insertion groove and the wire antenna being formed to penetrate through the interconnection part; a case frame of the electronic device formed so that the wire antenna is embedded between the case frame and the antenna pattern frame; and a circuit substrate that is electrically connected to the interconnection part to transmit and receive signals to and from the wire antenna.

The case frame of the electronic device is formed on the one surface of the antenna pattern frame by injection molding.

The one surface of the radiator frame may be formed with a coating part in order to increase the adhesion of the wire antenna in the insertion groove.

The insertion groove maybe formed to have a depth larger than the diameter or thickness of the wire antenna and the insertion groove may be subjected to thermal bonding to perform a surface treatment on the radiator frame.

The insertion groove may be formed on the side surface, the upper surface, or the side surface and upper surface of the radiator frame.

The insertion groove may be formed on the radiator frame so that the wire antenna is a roof antenna.

The wire antenna may be separated in plural.

The interconnection part may include an end of an interconnection pin formed to be bent at the opposite surface and the opposite surface of the radiator frame may be provided with an end connection groove to which the end of the interconnection part is fixed.

The interconnection part may be connected to the circuit substrate by any one of a C-clip and a coaxial cable.

The interconnection part may be exposed at the opposite surface in a spiral shape.

The interconnection part may be connected to the circuit substrate by any one of a C-clip and a coaxial cable.

According to another aspect of the present invention, there is provided a method for manufacturing an electronic device, including: forming an insertion groove into which a wire antenna is inserted on one surface of a radiator frame; inserting the wire antenna into a through hole formed at one point of the insertion groove to fix the wire antenna to the opposite surface of the radiator frame; forming an antenna pattern frame by inserting the wire antenna into the insertion groove; and injection-molding the antenna pattern frame by disposing the antenna pattern frame in a manufacturing mold having an inner space in a case shape of the electronic device.

The method for manufacturing an electronic device may further include coating the one surface of the radiator frame in order to increase the adhesion of the wire antenna in the insertion groove.

The insertion groove may be formed to have a depth larger than the diameter or thickness of the wire antenna and the insertion groove may be subjected to thermal bonding to perform a surface treatment on the radiator frame.

The insertion groove may be formed on the side surface, the upper surface, or the side surface and upper surface of the radiator frame.

The insertion groove may be formed on the radiator frame so that the wire antenna is a roof antenna.

The wire antenna may be cut to be separated in plural.

The method for manufacturing an electronic device may further include the interconnection part by bending the wire antenna at the opposite surface and fixing the interconnection part to the end connection groove on the opposite surface of the radiator frame.

The interconnection part may be connected to the circuit substrate by any one of a C-clip and a coaxial cable.

The method for manufacturing an electronic device may further include forming the interconnection part to expose the wire antenna at the opposite surface in a Spiral shape.

The interconnection part may be connected to the circuit substrate by any one of a C-clip and a coaxial cable.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is an exploded perspective view of a case of an electronic device according to an exemplary of the present invention, a mobile communication terminal;

FIG. 2 is a cross-sectional view schematically showing a first exemplary embodiment of an electrical connection shape between an antenna pattern frame and a circuit substrate;

FIG. 3 is a cross-sectional view schematically showing a second exemplary embodiment of an electrical connection shape between an antenna pattern frame and a circuit substrate;

FIG. 4 is a partially enlarged perspective view showing a first exemplary embodiment of “A” of FIG. 1;

FIG. 5 is a partially enlarged perspective view showing a second exemplary embodiment of “A” of FIG. 1;

FIG. 6 is a cross-sectional view of a first exemplary embodiment taken along line VI-VI of FIG. 1;

FIG. 7 is a cross-sectional view of a second exemplary embodiment taken along line VI-VI of FIG. 1;

FIG. 8 is a cross-sectional view of a third exemplary embodiment taken along line VI-VI of FIG. 1;

FIG. 9 is a perspective view schematically showing a first exemplary embodiment of an interconnection part of the antenna pattern frame according to the exemplary embodiment of the present invention;

FIG. 10 is a perspective view schematically showing a second exemplary embodiment of an interconnection part of the antenna pattern frame according to the exemplary embodiment of the present invention;

FIG. 11 is a perspective view schematically showing a shape in which the wire antenna is wound on the antenna pattern frame;

FIG. 12 is a cross-sectional view showing a shape in which the antenna pattern frame according to the exemplary embodiment of the present invention is disposed in a manufacturing mold of an electronic device; and

FIG. 13 is a cross-sectional view schematically showing a shape that the antenna pattern frame according to the exemplary embodiment of the present invention is injection-molded in the manufacturing mold of an electronic device.

### DETAILED DESCRIPTION OF THE PREFERRED EMBODIMENT

Exemplary embodiments of the present invention will now be described in detail with reference to the accompanying drawings. However, it should be noted that the spirit of the present invention is not limited to the embodiments set forth herein and those skilled in the art and understanding the present invention can easily accomplish retrogressive inventions or other embodiments included in the spirit of the present invention by the addition, modification, and removal of components within the same spirit, but those are to be construed as being included in the spirit of the present invention.

Further, throughout the drawings, the same or similar reference numerals will be used to designate the same components or like components having the same functions in the scope of the similar idea.

### Electronic Device

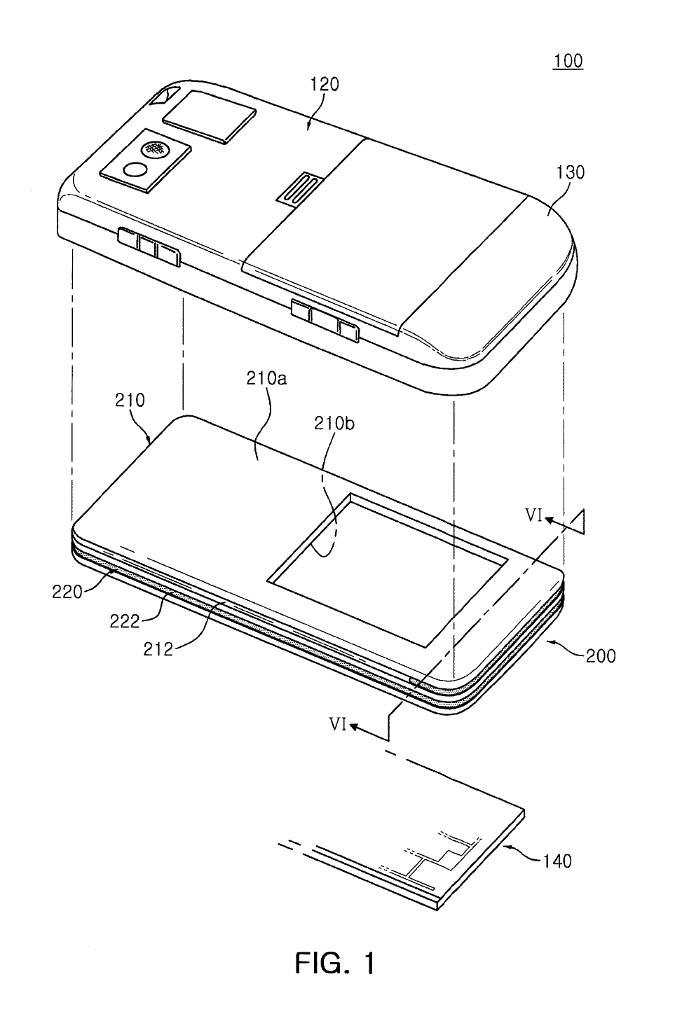

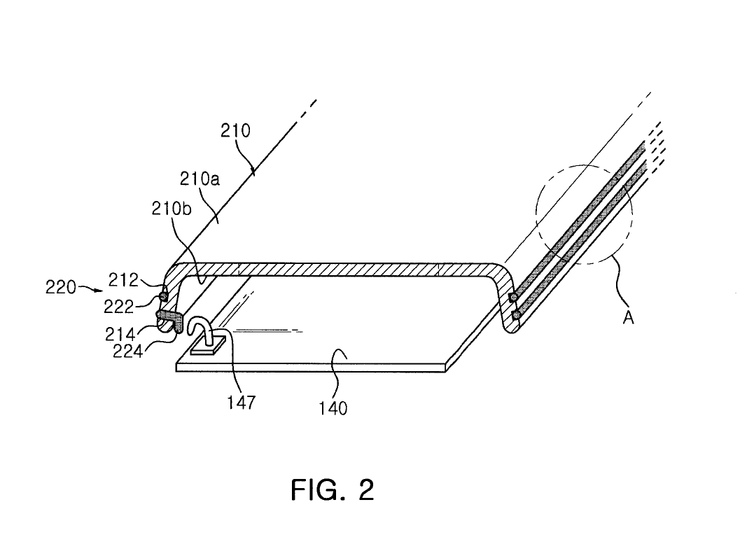

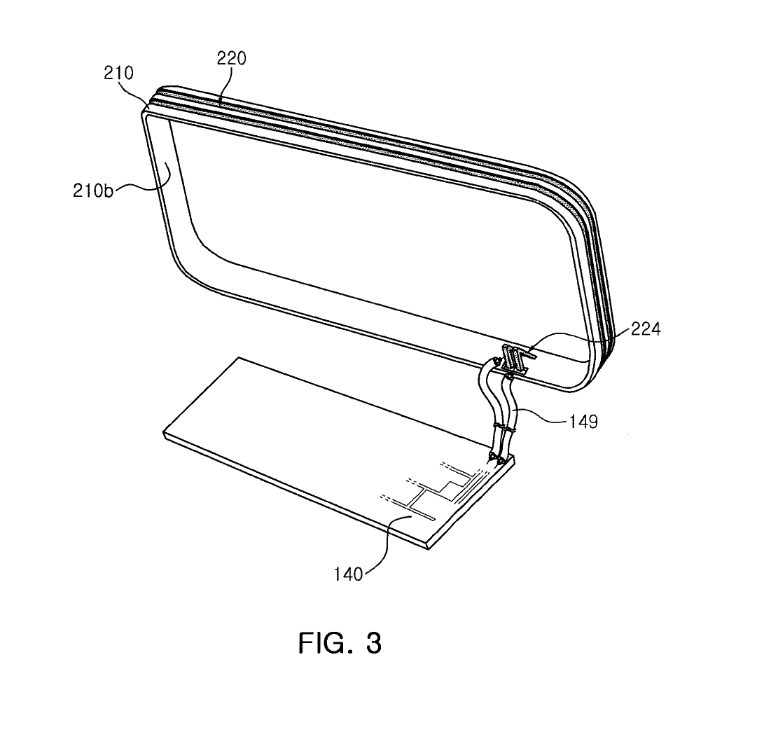

FIG. 1 is an exploded perspective view of a case of an electronic device according to an exemplary embodiment of the present invention, a mobile communication terminal, FIG. 2 is a cross-sectional view schematically showing a first exemplary embodiment of an electrical connection shape between an antenna pattern frame and a circuit substrate, and FIG. 3 is a cross-sectional view schematically showing a second exemplary embodiment of an electrical connection shape between an antenna pattern frame and a circuit substrate.

Referring to FIGS. 1 through 3, an antenna pattern frame 200 provided with an antenna pattern part 222 forming wire antennas 220 is fixed into a case 120 of an electronic device, a mobile communication terminal 100 according to an exemplary embodiment of the present invention, such that it can be appreciated that the wire antennas 220 are embedded in the case 120 of the mobile communication terminal.

The mobile communication terminal 100 that is one example of the electronic device may include the antenna pattern frame 200, a case frame 130, and a circuit substrate 140.

As shown in FIG. 1, the antenna pattern frame 200 may be fixed into the case frame 130 of the mobile communication terminal. Further, as will be described in detail below, the antenna pattern frame 200 is injection-molded by an electronic device manufacturing mold 400, such that it may be integrated with the case frame 130.

The circuit substrate 140 is mounted with circuit elements that transmit and receive signals to and from the wire antennas 220. The circuit substrate 140 is provided with connection wirings connected to an interconnection part 224 of the antenna pattern frame 200.

In this configuration, the connection of the interconnection part 224 between the circuit substrate 140 and the antenna pattern frame 220 may be made by a C-clip 149 provided in the circuit substrate 140 as shown in FIG. 2. However, as shown in FIG. 3, the circuit substrate 140 may be connected to the antenna pattern frame 220 by a coaxial cable 149 provided in the connection part of the circuit substrate 140.

Meanwhile, the mobile communication terminal 100 that is the electronic device according to the exemplary embodiment of the present invention may include all the technical features of the antenna pattern frame 200 to be described below.

### Antenna Pattern Frame

The antenna pattern frame 200 may include a radiator frame 210 and the wire antennas 220.

The radiator frame 210 is a plastic injection molded part. An insertion groove 212 may be formed on one surface 210a of the radiator frame 210 and a through part 214 connected from one point of the insertion groove 212 to an opposite surface 210b to the one surface 210a of the radiator frame 210 may be formed on the radiator frame 210.

The wire antenna 220 is a wire made of a conductive material. The radiator frame 210 may include the wire antenna 220 that includes the antenna pattern part 222 formed to be inserted into the insertion groove 212 and the interconnection part 224 formed to be exposed to the opposite surface 210b by extending from the antenna pattern part 222 and penetrating through the through part 214.

The wire antennas 220 may be lengthily formed to be appropriate to receive, in particular, broadcasting frequency bands that are a low frequency band. In other words, the insertion groove 212 formed in the radiator frame 210 may be formed on the side surface, the upper surface or the side surface and upper surface of the radiator frame 210.

At this time, the insertion groove 212 may be formed over the radiator frame 210 so that the wire antenna 220 is a roof antenna by being wound on the edges of the radiator frame 210.

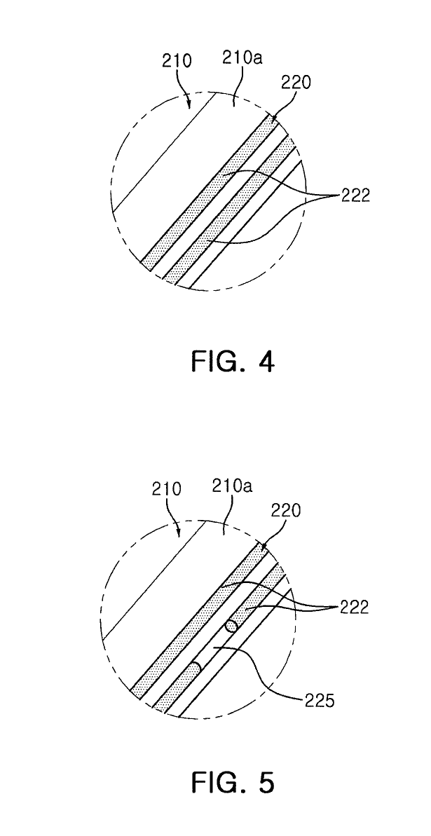

FIG. 4 is a partially enlarged perspective view showing a first exemplary embodiment of “A” of FIG. 1 and FIG. 5 is a partially enlarged perspective view showing a second exemplary embodiment of “A” of FIG. 1.

FIG. 4 shows a shape where the wire antenna 220 is continuously wound on the insertion groove 212 to be lengthily formed and FIG. 5 shows a case where the plurality of wire antennas 220 are wound on the insertion groove 212 to receive a plurality of frequency band.

At this time, the exemplary embodiment of FIG. 5 may form a cutting part 225 by forming the antenna pattern part 222 with one wire and then punching it.

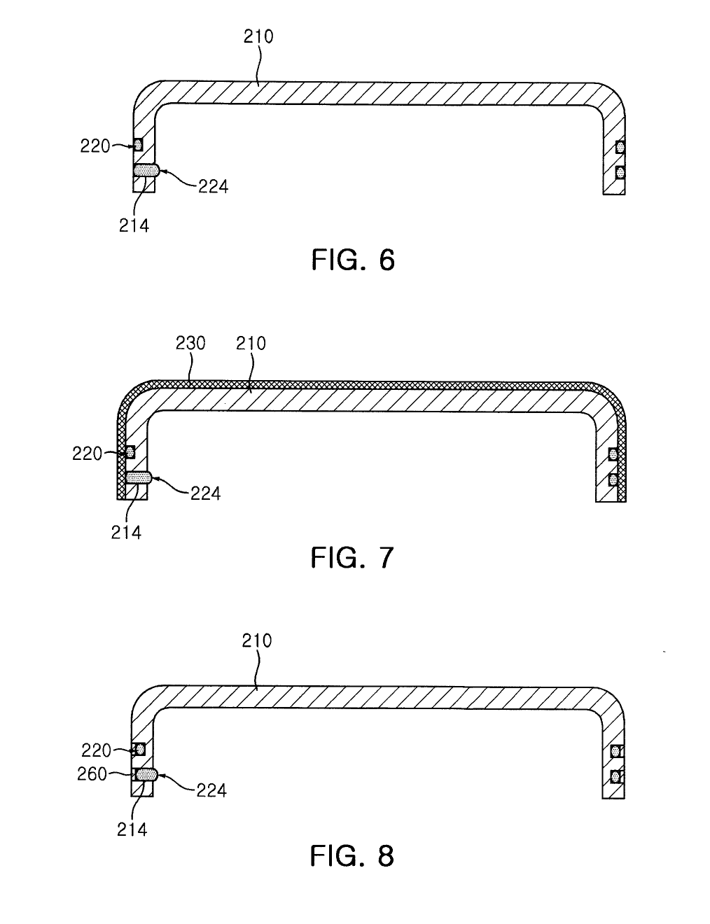

FIG. 6 is a cross-sectional view of a first exemplary embodiment taken along line VI-VI of FIG. 1, FIG. 7 is a cross-sectional view of a second exemplary embodiment taken along line VI-VI of FIG. 1, and FIG. 8 is a cross-sectional view of a third exemplary embodiment taken along line VI-VI of FIG. 1.

FIG. 6 shows the embodiment in which the insertion groove 212 is formed to have the same depth as the diameter and thickness of the wire antenna 220 so as to expose the wire antenna to the outside.

Since the wire antenna 220 is not necessarily a circular shape, the expression “thickness” was used herein.

FIG. 7 shows the structure where a coating part 230 is formed on the one surface 210a of the radiator frame 220 in order to increase adhesion between the wire antenna 220 and the radiator frame after winding the wire antenna 220 on the insertion groove 212.

The coating part 230 may be formed on a portion of the one surface 210a or over the one surface 210a and may also be formed on the opposite surface 210b.

FIG. 8 shows the case where the insertion groove 212 may be formed to have a depth larger than the diameter or the thickness of the wire antenna 220 and the wire antenna 220 may be more firmly fixed by thermal-bonding the insertion groove 212 Reference numeral 260 shows the case where the insertion groove 212 is embedded by the thermal bonding.

The thermal bonding process can smooth the surface of the antenna pattern frame 200 to increase the flowability of the injected liquid in the case that the case frame 130 is injection-molded.

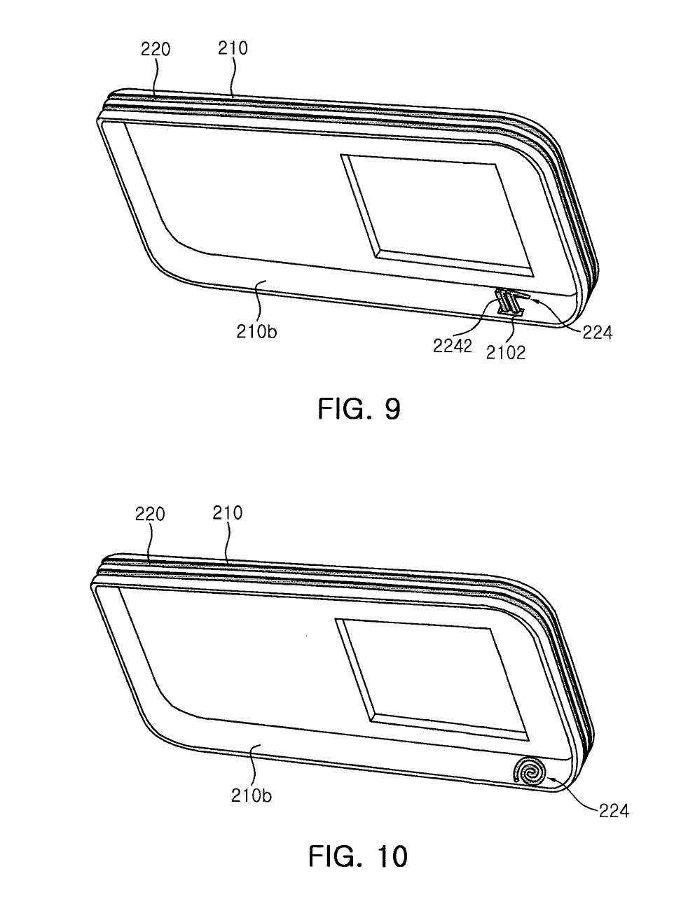

FIG. 9 is a perspective view schematically showing a first exemplary embodiment of an interconnection part of the antenna pattern frame according to the exemplary embodiment of the present invention, and FIG. 10 is a perspective view schematically showing a second exemplary embodiment of an interconnection part of the antenna pattern frame according to the exemplary embodiment of the present invention.

FIGS. 9 and 10 show the shape where the interconnection part 224 of the antenna pattern frame 220 is formed.

FIG. 9 shows the case where the interconnection part 224 may include an end 2242 of an interconnection pin formed to be bent at the opposite surface 210b. The interconnection part 224 is formed to be bent and thus may have tension, such that it may be easily connected with the circuit substrate 140. Further, the end 2242 of the interconnection part may be fixed to an end connection groove 2102 that is formed on the opposite surface 210b of the radiator frame 210.

FIG. 10 shows a case where the interconnection part 224 may be exposed to the opposite surface 210b of the radiator frame 210 in a spiral shape. The structure of the interconnection part 224 according to the exemplary embodiment may stably contact the circuit substrate 140 by expanding the contact range therebetween.

### Method for Manufacturing Electronic Device

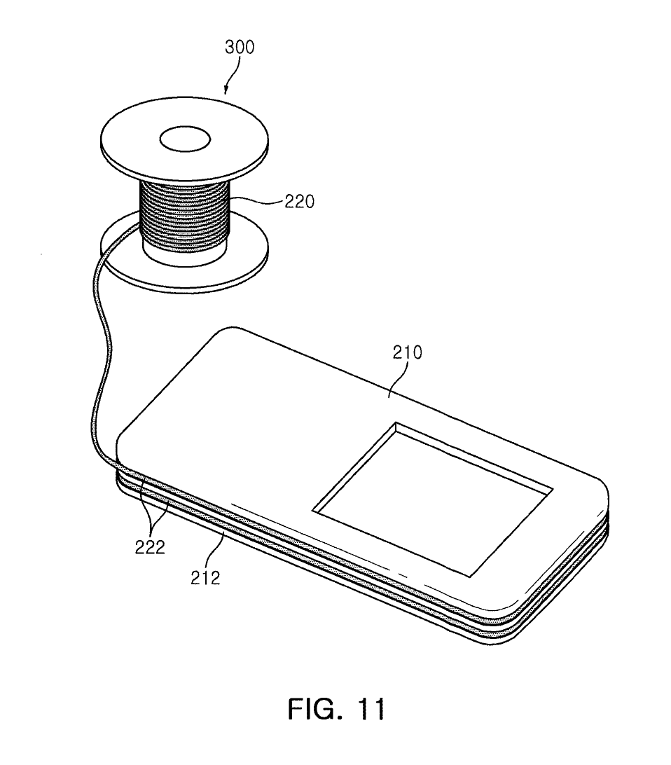

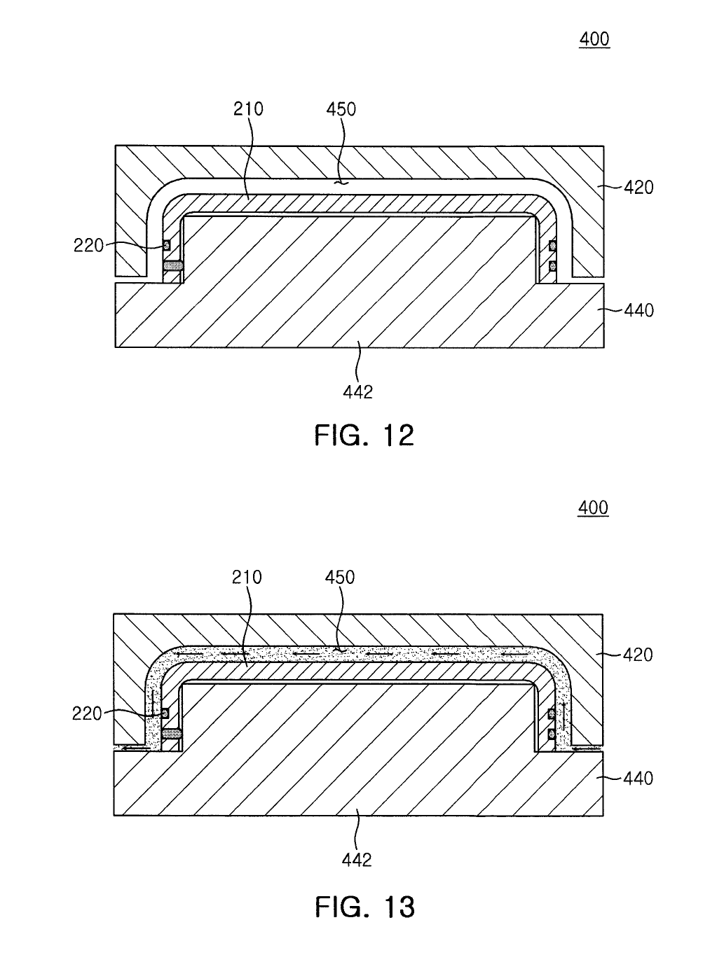

FIG. 11 is a perspective view schematically showing a shape in which the wire antenna is wound on the antenna pattern frame, FIG. 12 is a cross-sectional view showing a shape in which the antenna pattern frame according to the exemplary embodiment of the present invention is disposed in a manufacturing mold of an electronic device, and FIG. 13 is a cross-sectional view schematically showing a shape in which the antenna pattern frame according to the exemplary embodiment of the present invention is injection-molded in the manufacturing mold of an electronic device.

First, the insertion groove 212 in which the wire antenna 220 is inserted is formed on the one surface 210a of the radiator frame 210. The wire antenna 220 is inserted into the through hole 214 formed at one point of the inserting groove 212 and thus, is fixed to the opposite surface 210b of the radiator frame 210.

If one end of the wire antenna 220 is fixed to the radiator frame 210, the wire antenna 220 is inserted into the insertion groove 212 to form the antenna pattern frame 200.

At this time, the number of wire antennas 220 may be provided as needed in the state where it is wound on a winding machine 300.

The manufactured antenna pattern frame 200 may be disposed in the manufacturing mold 400 having an inner space 450 of the case shape of the electronic device to be injection-molded.

The one surface 210a of the antenna pattern frame 200 is directed to the inner space 450, such that the wire antenna 220 may be embedded in the case frame 130 of the electronic device.

Meanwhile, the one surface of the antenna pattern frame 200 is surface-coated or thermal-bonded, thereby making it possible to improve the flowability of resin when performing the injection molding.

Further, the interconnection part 224 may be formed on the opposite surface of the antenna pattern frame 200 and the process of forming the interconnection part 224 may be performed in any process among the manufacturing processes, such as when the wire antenna 220 is fixed to the insertion groove 212 or after the injection molding is performed, or the like.

When the interconnection part 224 is formed, it may be electrically connected to the connection part of the circuit substrate 140 by a C-clip or a coaxial cable, or the like.

As set forth above, according to the antenna pattern frame, the electronic device provided with the antenna pattern frame, and the method for manufacturing the electronic device of the present invention, the wire antenna is fixed to the radiator frame, thereby making it possible to simplify the manufacturing process and reduce the wasted amount of radiator to save manufacturing costs.

Further, the present invention can easily secure the length of the radiator to receive the signals of the low frequency band and can greatly simplify the manufacturing process, since there is no need to dispose the wire antenna in a separate mold and perform the injection molding thereon.

While the present invention has been shown and described in connection with the exemplary embodiments, it will be apparent to those skilled in the art that modifications and variations can be made without departing from the spirit and scope of the invention as defined by the appended claims.

What is claimed is:

1. An antenna pattern frame, comprising:
a radiator frame that has an insertion groove formed on one surface of the radiator frame and is provided with a through part connected from one point of the insertion groove to an opposite surface to the one surface of the radiator frame; and
a wire antenna that includes an antenna pattern part formed to be inserted into the insertion groove and an interconnection part formed to be exposed to the opposite surface by extending from the antenna pattern part and penetrating through the through part.

2. The antenna pattern frame of claim 1, wherein the insertion groove is formed at the same depth as the diameter or thickness of the wire antenna.

3. The antenna pattern frame of claim 1, wherein the insertion groove is formed to have a depth larger than the diameter or thickness of the wire antenna

4. The antenna pattern frame of claim 1, further comprising a coating part formed on the one surface of the radiator frame in order to increase the adhesion between the wire antenna and the radiator frame.

5. The antenna pattern frame of claim 1, wherein the insertion groove is surface-treated by thermal bonding.

6. The antenna pattern frame of claim 1, wherein the insertion groove is formed on the side surface, the upper surface, or the side surface and the upper surface of the radiator frame.

7. The antenna pattern frame of claim 1, wherein the insertion groove is formed on the radiator frame so that the wire antenna is a roof antenna.

8. The antenna pattern frame of claim 1, wherein the wire antenna is separated in plural.

9. The antenna pattern frame of claim 1, wherein the interconnection part includes an end of an interconnection pin formed to be bent at the opposite surface and the opposite surface of the radiator frame is provided with an end connection groove to which the end of the interconnection part is fixed.

10. The antenna pattern frame of claim 1, wherein the interconnection part is exposed at the opposite surface in a spiral shape.

11. An electronic device, comprising:
an antenna pattern frame that has an insertion groove formed on one surface of the antenna pattern frame and is provided with an interconnection part formed on an opposite surface to the one surface, a wire antenna being inserted into the insertion groove and the wire antenna being formed to penetrate through the interconnection part;
a case frame formed so that the wire antenna is embedded between the case frame and the antenna pattern frame; and
a circuit substrate that is electrically connected to the interconnection part to transmit and receive signals to and from the wire antenna.

12. The electronic device of claim 11, wherein the case frame is formed on the one surface of the antenna pattern frame by injection molding.

13. The electronic device of claim 11, wherein the one surface of the radiator frame is formed with a coating part in order to increase the adhesion of the wire antenna in the insertion groove.

14. The electronic device of claim 11, wherein the insertion groove is formed to have a depth larger than the diameter or thickness of the wire antenna and the insertion groove is subjected to thermal bonding to perform a surface treatment on the radiator frame.

15. The electronic device of claim 11, wherein the insertion groove is formed on the side surface, the upper surface, or the side surface and upper surface of the radiator frame.

16. The electronic device of claim 11, wherein the insertion groove is formed on the radiator frame so that the wire antenna is a roof antenna.

17. The electronic device of claim 11, wherein the wire antenna is separated in plural.

18. The electronic device of claim 11, wherein the interconnection part includes an end of an interconnection pin formed to be bent at the opposite surface and the opposite surface of the radiator frame is provided with an end connection groove to which the end of the interconnection part is fixed.

19. The electronic device of claim 18, wherein the interconnection part is connected to the circuit substrate by any one of a C-clip and a coaxial cable.

20. The electronic device of claim 11, wherein the interconnection part is exposed at the opposite surface in a spiral shape.

21. The electronic device of claim 20, wherein the interconnection part is connected to the circuit substrate by any one of a C-clip and a coaxial cable.

22. A method for manufacturing an electronic device, comprising:
forming an insertion groove into which a wire antenna is inserted on one surface of a radiator frame;
inserting the wire antenna into a through hole formed at one point of the insertion groove to fix the wire antenna to the opposite surface of the radiator frame;
forming an antenna pattern frame by inserting the wire antenna into the insertion groove; and
injection-molding the antenna pattern frame by disposing the antenna pattern frame in a manufacturing mold having an inner space in a case shape of the electronic device.

23. The method for manufacturing an electronic device of claim 22, further comprising coating the one surface of the radiator frame in order to increase the adhesion of the wire antenna in the insertion groove.

24. The method for manufacturing an electronic device of claim 22, wherein the insertion groove is formed to have a depth larger than the diameter or thickness of the wire antenna and the insertion groove is subjected to thermal bonding to perform a surface treatment on the radiator frame.

25. The method for manufacturing an electronic device of claim 22, wherein the insertion groove is formed on the side surface, the upper surface, or the side surface and upper surface of the radiator frame.

26. The method for manufacturing an electronic device of claim 22, wherein the insertion groove is formed on the radiator frame so that the wire antenna is a roof antenna.

27. The method for manufacturing an electronic device of claim 22, wherein the wire antenna is cut to be separated in plural.

28. The method for manufacturing an electronic device of claim 22, further comprising forming the interconnection part by bending the wire antenna at the opposite surface and fixing the interconnection part to the end connection groove on the opposite surface of the radiator frame.

29. The method for manufacturing an electronic device of claim 28, wherein the interconnection part is connected to the circuit substrate by any one of a C-clip and a coaxial cable.

30. The method for manufacturing an electronic device of claim 22, further comprising forming the interconnection part to expose the wire antenna at the opposite surface in a spiral shape.

31. The method for manufacturing an electronic device of claim 30, wherein the interconnection part is connected to the circuit substrate by any one of a C-clip and a coaxial cable.
